(19) United States
(12) Patent Application Publication
(10) Pub. No.: US 2026/0051691 A1
(43) Pub. Date: Feb. 19, 2026

(54) MODULAR SYSTEM BACKPLANE AND METHOD

(71) Applicant: Rockwell Collins, Inc., Cedar Rapids, IA (US)

(72) Inventors: Anders P. WALKER, Marion, IA (US); Aaron J. SMITH, Marion, IA (US); Joshua M. PATOCKA, Cedar Rapids, IA (US); Joshua C. BEALS, Cedar Rapids, IA (US); Brianne A. RIEHL, Marion, IA (US); Robert A. NEWGARD, Sun City West, AZ (US); Bradley SCHROEDER, Glendale, AZ (US)

(73) Assignee: Rockwell Collins, Inc., Cedar Rapids, IA (US)

(21) Appl. No.: 18/808,784

(22) Filed: Aug. 19, 2024

(51) Int. Cl. H01R 13/514; H01R 13/518; H05K 7/14

(52) U.S. Cl. CPC H01R 13/514; H01R 13/518; H05K 7/1452

(57) ABSTRACT

A modular system backplane can be built from a variety of individual backplane modules. The backplane modules may have edge connectors for connection to one another to provide a modular system backplane for rapid development of a backplane for demonstration and/or prototyping of electronic devices using electronic modules conforming with the open system standard. A backplane module can be configured with spaced electronic module connectors for providing between two and five slots for single-slot or dual-slot electronic modules conforming with an open system standard. Various backplane modules may be designed for specific functions, such as providing power, RF communications, networking, inertial and navigation sensing, etc. using a variety of electronic modules conforming with the open system standard. A set of backplane modules can then be connected to each other as a modular system backplane to provide a particular backplane for the desired functionality.

### FIELD OF THE INVENTION

The subject matter disclosed herein relates to a backplane design and method and, in particular, to a modular system backplane and method for modular open system electronic modules.

### BACKGROUND OF THE INVENTION

A Modular Open Systems Approach (MOSA) is as a technical and logistical strategy for designing affordable and adaptable systems. Various MOSAs have been developed for electronic modules, such as by the Open Group Sensor Open System Architecture (SOSA™) Consortium, which developed the SOSA specification for electronic sensors, and by the VMEbus International Trade Association (VITA), which developed numerous standards, including the VPX (VITA 46), VNX (VITA 74), and VNX+ (VITA 90) specifications, for various electronic modules, slots, and backplanes.

Typically, a particular backplane for connecting a plurality of modules will be designed or optimized for a particular application or end use. However, designing such a particular backplane for demonstration or prototyping purposes adds to the time and cost of development.

The above information disclosed in this Background section is only for understanding of the background of the inventive concepts and, therefore, it may contain information that does not constitute prior art.

### SUMMARY OF THE INVENTION

The present disclosure is directed, in a first aspect, to a backplane module for a modular system backplane. The backplane module includes a substrate having a first face, a second face opposite the first face, a first edge and a second edge opposite and substantially parallel to the first edge. A first multi-pin electrical connector is disposed adjacent the first edge and a second multi-pin electrical connector is disposed adjacent the second edge. A plurality of electrical conductors extending between pins of the first multi-pin connector and pins of the second multi-pin connector, and a plurality of third multi-pin connectors are disposed on the first face and have pins in electrical contact with one or more of the plurality of electrical conductors. The first multi-pin connector is a male connector configured to physically and electrically interface with the second multi-pin connector that is a female connector so that various backplane modules may be connected to one another to form a modular system backplane.

In an embodiment, the plurality of third multi-pin connectors may be configured and spaced for connection to electronic modules conforming to an open system standard.

In one or more other embodiments, the first multi-pin connector and the second multi-pin connector may be disposed on the second face of the substrate, and the first multi-pin connector and the second multi-pin connector may be 150-pin edge connectors.

In another embodiment, the backplane module may further include a first 150-pin mezzanine connector disposed on the second face of the substrate and electrically connected to the plurality of electrical conductors.

In yet another embodiment, the backplane module may further include a network input/output transfer circuit board having: a first side and a second side; a second 150-pin mezzanine connector disposed on the first side and configured to physically and electrically interface with the first 150-pin mezzanine connector; and a plurality of networking connectors disposed on and extending from the second side.

In one or more embodiments, the backplane module may further include a digital input/output transfer board having: a first side and a second side; a second 150-pin mezzanine connector disposed on the first side and configured to physically and electrically interface with the first 150-pin mezzanine connector; a cutout configured for RF connections; and at least one digital input/output connector disposed on and extending from the second side.

The present disclosure is directed, in a second aspect, to a modular system backplane. The modular system backplane includes at least a first backplane module and a second backplane module. The first backplane module includes: a first substrate having a first face, a second face opposite the first face, a first edge and a second edge opposite and substantially parallel to the first edge; a first multi-pin electrical connector disposed adjacent the first edge; a second multi-pin electrical connector disposed adjacent the second edge; a plurality of first electrical conductors extending between pins of the first multi-pin connector and pins of the second multi-pin connector; and a plurality of third multi-pin connectors disposed on the first face and having pins in electrical contact with one or more of the plurality of first electrical conductors. The second backplane module includes: a second substrate having third face, a fourth face, a third edge, and a fourth edge opposite and substantially parallel to the third edge; a fourth multi-pin electrical connector disposed adjacent the third edge; a fifth multi-pin electrical connector disposed adjacent the fourth edge; a plurality of second electrical conductors extending between pins of the fourth multi-pin connector and pins of the fifth multi-pin connector; and a plurality of sixth multi-pin connectors disposed on the third face and having pins in electrical contact with one or more of the plurality of second electrical conductors. The second multi-pin connector is configured to physically and electrically interface with the fourth multi-pin connector so that first backplane module and second backplane module may be connected to one another.

In one or more embodiments, the plurality of third multi-pin connectors and the plurality of sixth multi-pin connectors may be configured and spaced for connection to electronic modules conforming to an open system standard.

In an embodiment, at least one of the plurality of third multi-pin connectors may be configured for a filter module and at least one of the plurality of third multi-pin connectors may be configured for a power supply unit (PSU) module.

In a further embodiment, the first multi-pin connector may be a first eight-pin power mezzanine connector disposed on the second face of the first substrate.

In yet another embodiment, the modular system backplane may further include a power circuit board having: a first side and a second side; a second eight-pin power mezzanine connector disposed on the first side and configured to physically and electrically interface with the first eight-pin power mezzanine connector; and a multi-pin power input connector disposed on and extending from the second side.

In a further embodiment, the second multi-pin connector may be disposed on the second face of the first substrate, and the fourth multi-pin connector and the fifth multi-pin connector may be disposed on the fourth face of the second substrate, and the second multi-pin connector, the fourth multi-pin connector, and the fifth multi-pin connector may be 150-pin edge connectors.

In another embodiment, the modular system backplane may further include a first 150-pin mezzanine connector disposed on the fourth face of the second substrate and electrically connected to the plurality of second electrical conductors.

In an embodiment, the modular system backplane may further include a network input/output transfer circuit board having: a first side and a second side; a second 150-pin mezzanine connector disposed on the first side and configured to physically and electrically interface with the first 150-pin mezzanine connector; and a plurality of networking connectors disposed on and extending from the second side.

In yet another embodiment, the modular system backplane may further include a digital input/output transfer board having: a first side and a second side; a second 150-pin mezzanine connector disposed on the first side and configured to physically and electrically interface with the first 150-pin mezzanine connector; a cutout configured for RF connections; and at least one digital input/output connector disposed on and extending from the second side.

In an embodiment, the third multi-pin connectors are 320-pin connectors and the sixth multi-pin connectors are 400-pin connectors.

In another embodiment, the third multi-pin connectors are 320-pin centered connectors and the sixth multi-pin connectors are 320-pin left-justified/half aperture with RF connectors.

The present disclosure is directed, in a third aspect, to a method of providing a modular system backplane. The method includes providing a first backplane module including: a first substrate having a first face, a second face opposite the first face, a first edge and a second edge opposite and substantially parallel to the first edge; a first multi-pin electrical connector disposed adjacent the first edge; a second multi-pin electrical connector disposed adjacent the second edge; a plurality of first electrical conductors extending between pins of the first multi-pin connector and pins of the second multi-pin connector; and a plurality of third multi-pin connectors disposed on the first face and having pins in electrical contact with one or more of the plurality of first electrical conductors. The method also includes providing a second backplane module including: a second substrate having third face, a fourth face, a third edge, and a fourth edge opposite and substantially parallel to the third edge; a fourth multi-pin electrical connector disposed adjacent the third edge; a fifth multi-pin electrical connector disposed adjacent the fourth edge; a plurality of second electrical conductors extending between pins of the fourth multi-pin connector and pins of the fifth multi-pin connector; and a plurality of sixth multi-pin connectors disposed on the third face and having pins in electrical contact with one or more of the plurality of second electrical conductors. The method also includes connecting the second multi-pin connector, physically and electrically, to the fourth multi-pin connector.

In an embodiment, the method may further include configuring and spacing the plurality of third multi-pin connectors and the plurality of sixth multi-pin connectors for connection to electronic modules conforming to an open system standard.

In another embodiment, the method may further include providing an additional backplane module including: an additional substrate having fifth face, a sixth face, a fifth edge, and a sixth edge opposite and substantially parallel to the fifth edge; a seventh multi-pin electrical connector disposed adjacent the fifth edge; an eighth multi-pin electrical connector disposed adjacent the sixth edge; a plurality of third electrical conductors extending between pins of the sixth multi-pin connector and pins of the fifth multi-pin connector; and a plurality of ninth multi-pin connectors disposed on the fifth face and having pins in electrical contact with one or more of the plurality of third electrical conductors; and connecting the fifth multi-pin connector, physically and electrically, to the seventh multi-pin connector.

### BRIEF DESCRIPTION OF FIGURES

The features of the disclosure believed to be novel and the elements characteristic of the invention are set forth with particularity in the appended claims. The figures are for illustration purposes only and are not drawn to scale. The disclosure itself, however, both as to organization and method of operation, can best be understood by reference to the description of the preferred embodiment(s) which follows, taken in conjunction with the accompanying drawings in which:

FIG. 1A is a plan view of one side of a first example of a power backplane module in accordance with the present disclosure;

FIG. 1B is a plan view of the other side of the first example of a power backplane module in accordance with the present disclosure;

FIG. 1C is a plan view of one side of a power circuit board usable with the first example of a power backplane module in accordance with the present disclosure;

FIG. 1D is a plan view of another side of the power circuit board usable with the first example of a power backplane module in accordance with the present disclosure;

FIGS. 1E and 1F are orthogonal views of the power circuit board connected to the first example of a power backplane module in accordance with the present disclosure;

FIG. 2A is a plan view of one side of a second example of a network backplane module in accordance with the present disclosure;

FIG. 2B is a plan view of the other side of the second example of a network backplane module in accordance with the present disclosure;

FIG. 3A is a plan view of one side of the second example of a network backplane module connected to the first example of a power backplane module in accordance with the present disclosure;

FIG. 3B is a plan view of the other side of the second example of a network backplane module connected to the first example of a power backplane module in accordance with the present disclosure;

FIG. 4A is a plan view of one side of a network input/output circuit board usable with the second example of a network backplane module in accordance with the present disclosure;

FIG. 4B is a plan view of the other side of a network input/output circuit board usable with the second example of a network backplane module in accordance with the present disclosure;

FIGS. 4C and 4D are orthogonal views of the network input/output circuit board connected to the second example of a network backplane, which is connected with the first example of a power backplane module in accordance with the present disclosure;

FIG. 5A is a plan view of one side of a third example of a radio frequency auxiliary functions (RF Aux) backplane module in accordance with the present disclosure;

FIG. 5B is a plan view of the other side of the third example of an RF Aux backplane module in accordance with the present disclosure;

FIG. 6A is a plan view of one side of a fourth example of a digital backplane module in accordance with the present disclosure;

FIG. 6B is a plan view of the other side of the fourth example of a digital backplane module in accordance with the present disclosure;

FIG. 7A is a plan view of one side of a digital input/output transfer circuit board usable with the fourth example of a digital backplane module in accordance with the present disclosure;

FIG. 7B is a plan view of another side of the digital input/output transfer circuit board usable with the fourth example of a digital backplane module in accordance with the present disclosure;

FIGS. 7C and 7D are orthogonal views of the digital input/output transfer circuit board connected with the fourth example of a digital backplane module in accordance with the present disclosure;

FIGS. 8A, 8B, and 8C are elevation views of examples of modular system backplanes in accordance with the present disclosure disposed in a corresponding modular chassis; and

FIG. 9 is s flow diagram of a method of providing a modular system backplane.

### DETAILED DESCRIPTION OF THE INVENTION

The embodiments of the present disclosure can comprise, consist of, and consist essentially of the features and/or steps described herein, as well as any of the additional or optional ingredients, components, steps, or limitations described herein or would otherwise be appreciated by one of skill in the art. It will be understood that, although the terms “first,” “second,” “third,” and the like may be used herein to describe various elements, these elements should not be limited by these terms. These terms are only used to distinguish one element from another element. Thus, “a first element” discussed below could be termed “a second element” or “a third element,” and “a second element” and “a third element” may be termed likewise without departing from the teachings herein. Similarly, it may be understood that spatially relative terms such as “front,” “top,” “bottom,” “side” and the like may be used herein for ease of description to describe the relations between one element or component and another element or component as illustrated in the drawings. It will be understood that the spatially relative terms are intended to encompass different orientations of the device in use or operation, in addition to the orientation depicted in the drawings.

The present disclosure is directed to a modular system backplane that can be made from a variety of individual backplane modules. The backplane modules may have edge connectors for connection to one another to provide a modular system backplane for rapid development of a backplane for demonstration and/or prototyping of electronic devices using electronic modules conforming with the open system standard. A backplane module can be configured with spaced electronic module connectors for providing between two and five slots for single-slot or multi-slot electronic modules conforming with an open system standard. Various backplane modules may be designed for specific functions, such as providing power, RF communications, networking, digital processing, inertial and navigation sensing, etc. using a variety of electronic modules conforming with the open system standard. A set of backplane modules can then be connected to each other as a modular system backplane to provide a particular backplane for the desired functionality.

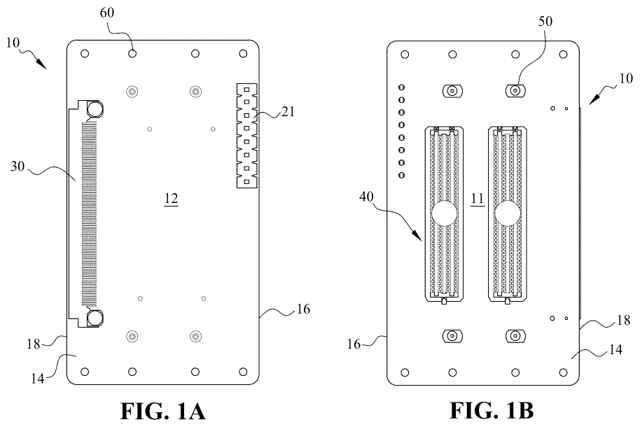

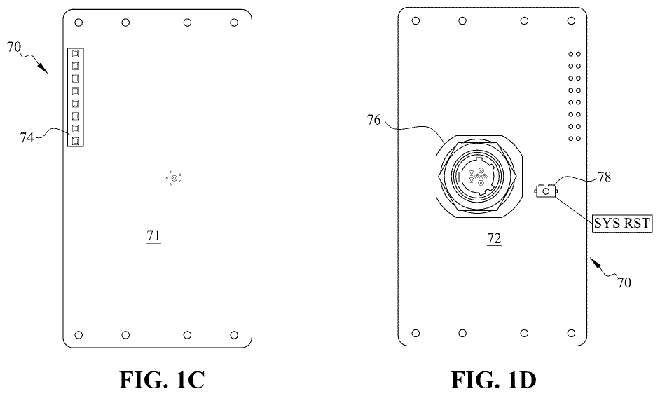

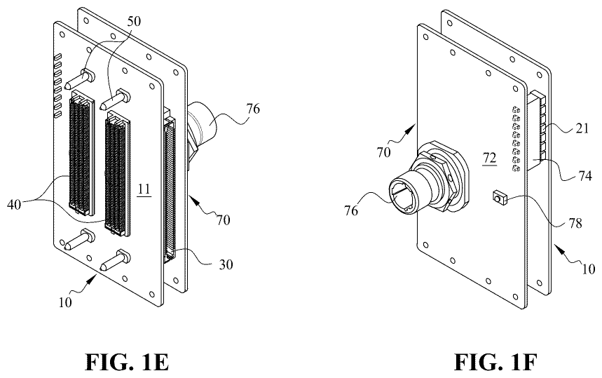

With reference to FIGS. 1A, 1B, 2A, 2B, 5A, 5B, 6A, and 6B, a backplane module 10 for a modular system backplane includes a substrate 14 having a first face 11, a second face 12 opposite the first face 11, a first edge 16 and a second edge 18 opposite and substantially parallel to the first edge 16. The substrate 14 may be made of any materials suitable for PCB manufacture and may include multiple layers.

The backplane module 10 includes a first multi-pin electrical connector 20 or 21 disposed adjacent the first edge 16 and a second multi-pin electrical connector 30 disposed adjacent the second edge 18. In one or more embodiments, the first multi-pin electrical connector 20 may be a multi-pin male connector that extends beyond first edge 16 and the second multi-pin electrical connector 30 may be a complementary multi-pin female connector that is substantially flush with second edge 18 and is configured to physically and electrically mate (i.e., connect) with the multi-pin male connector. A connection direction of the first and second multi-pin connectors 20 and 30 may be substantially parallel to the substrate 14 such that two backplane modules 10 may be physically and electrically connected to each other when a second edge 18 of one backplane module 10 is adjacent a first edge 16 of another backplane module 10. In an example embodiment, the first and second multi-pin connectors 20 and 30 are disposed on the second face 12 of substrate 14 and may be 150-pin Searay™ edge connectors from Samtec.

In one or more other embodiments, as illustrated in FIGS. 1A and 1B, the backplane module 10 may be a power backplane module wherein the first multi-pin connector 21 may be a multi-pin power connector, such as an eight-pin power connector extending perpendicular to substrate 14, for supplying power to selected pins of a modular system backplane.

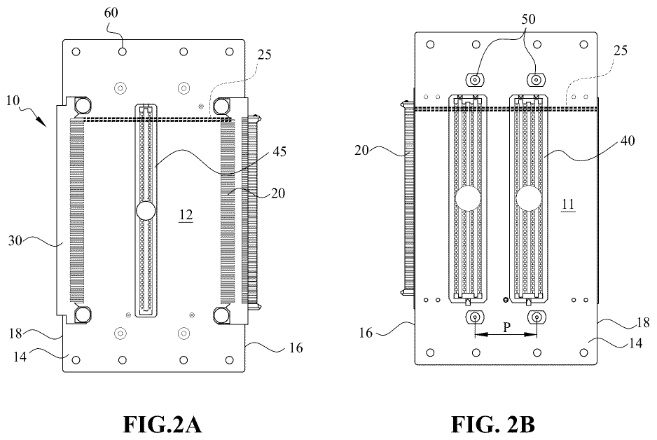

Referring to FIGS. 2A and 2B, the backplane module 10 further includes a plurality of electrical conductors 25 extending between pins of the first multi-pin connector 20 and pins of the second multi-pin connector 30. In one or more embodiments, the electrical conductors 25 may be formed as traces on an interior layer of substrate 14, and thus are not visible. For ease of description, only a couple of the electrical conductors 25 are illustrated in phantom (i.e., via dashed lines) in FIGS. 2A and 2B, but a plurality of electrical conductors 25 are further included in, but not visible on, the backplane modules 10 illustrated in FIGS. 1A, 1B, 3A, 3B, 4C, 4D, 5A, 5B, 6A, 6B, 7C, 8A, 8B, and 8C. In one or more embodiments, 150 electrical conductors 25 may be embedded in substrate 14 and extend between pins of the first multi-pin connector 20 and pins of the second multi-pin connector 30. In various embodiments, the electrical conductors 25 may form a portion of a passive backplane.

In one or more embodiments, the backplane module 10 includes a plurality of third multi-pin connectors 40 disposed on the first face 11 of the substrate 14. The third multi-pin connectors 40 may include pins in electrical contact with one or more of the plurality of electrical conductors 25. In various embodiments, the plurality of third multi-pin connectors 40 may be configured and spaced for connection to electronic modules conforming to an open system standard. For example, third multi-pin connectors 40 may be 400-pin Searay™ connectors from Samtac that are centered/no aperture or 320-pin Searay™ connectors from Samtec that are centered/no aperture or are left-justified/half aperture with RF. Locating pins 50 may be provided for each third multi-pin connector 40 and may be spaced at a predetermined pitch P greater than a height of an electronic module conforming to the open system standard. For example, in an open system standard with 19 mm modules, the predetermined pitch may be approximately 20 mm (e.g., 20.32 mm). In various examples, the backplane modules 10 may include between two and five of the third multi-pin connectors 40 in 2-slot, 3-slot, 4-slot, or 5-slot configurations and may, in some examples, include fewer third multi-pin connectors 40 than slots. However, the present disclosure is not limited to these examples and other numbers of slots (e.g., 7, 9, 11, etc.) and third multi-pin connectors 40 are possible.

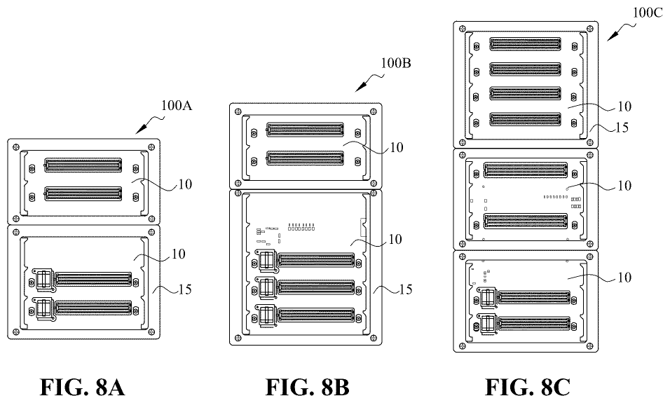

Further, in one or more embodiments, the backplane modules 10 of FIGS. 1A, 1B, 2A, 2B, 3A, 3B, 4C, 4D, 5A, 5B, 6A, 6B, and 7C may include a plurality of mounting holes 60. As illustrated in FIGS. 8A, 8B, and 8C, the mounting holes 60 may be used to mount backplane modules 10 onto a chassis, such as a modular system chassis.

With reference to FIGS. 2A, 3A, and 6A, backplane module 10 may further include a first mezzanine connector 45 disposed on the second face 12 of the substrate 14 and electrically connected to the plurality of electrical conductors 25. In an example embodiment, the first mezzanine connector 45 is a first 150-pin Searay™ mezzanine connector from Samtac. The first mezzanine connector 45 can be used to transfer power and signals from electrical connectors 25 to a mezzanine card having a circuit board for performing additional processing and/or having one or more connectors.

By extending the power and signals to/from the electrical connectors 25 of backplane module 10 operating at a selected bus speed to a mezzanine card, higher-speed processing and signaling may take place on the mezzanine card. Additionally and/or alternatively, physical connectors or switches that extend through a circuit board, and would thus interrupt/interfere with the electrical connectors 25 if mounted on the backplane module 10, may be mounted on the mezzanine card to avoid such interruption/interference.

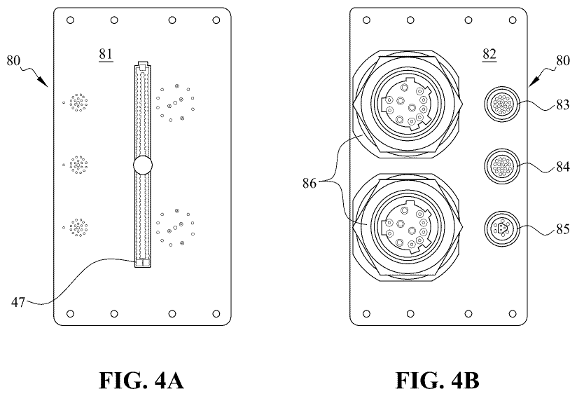

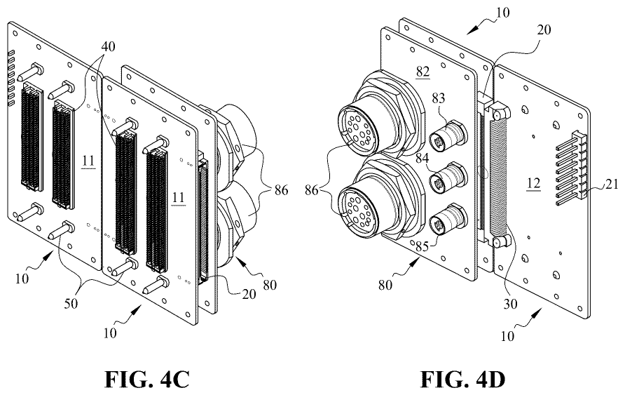

Referring to FIGS. 4A-4D, in one or more embodiments, a mezzanine card may include a network input/output transfer circuit board (network IOTB) 80. Network IOTB 80 may be formed as a PCB and include a first side 81 and a second side 82. A second mezzanine connector 47, such as a second 150-pin Searay™ mezzanine connector from Samtac, may be disposed on the first side 81 and be configured to physically and electrically interface with the first 150-pin mezzanine connector 45 in order to connect to a network backplane module 10.

A plurality of networking connectors 83, 84, 85, and 86 may be disposed on and extend from the second side 82 of network IOTB 80. In an example embodiment, connector 83 may be a 19-pin LVDS connection (having 8 pairs+Serial), connector 84 may be a 9-pin USB 3.0 connection, connector 85 may be a 19-pin DisplayPort connection, and connectors 86 may be 22-pin Ethernet connections.

As illustrated in FIGS. 4C and 4D, the network IOTB 80 mezzanine card may be installed onto a network backplane module 10 by connecting the first mezzanine connector 45 (not shown) of the network backplane module 10 to the second mezzanine connector 47 (not shown) of the network IOTB 80 mezzanine card.

Referring to FIGS. 2B, 3B, and 4C, an embodiment of a network backplane module 10 for use with the network IOTB 80 mezzanine card may include centered/no aperture 400-pin Searay™ connectors as the third multi-pin connectors 40 disposed on the first face 11 of the substrate 14. The third multi-pin connectors 40 may then be connected to networking electronic modules conforming with the open system standard, for example that use mating 400-pin Searay™ connectors. Although illustrated with two of the third multi-pin connectors 40, embodiments of network backplane modules are not limited to this embodiment and may include more than two of the third multi-pin connectors 40.

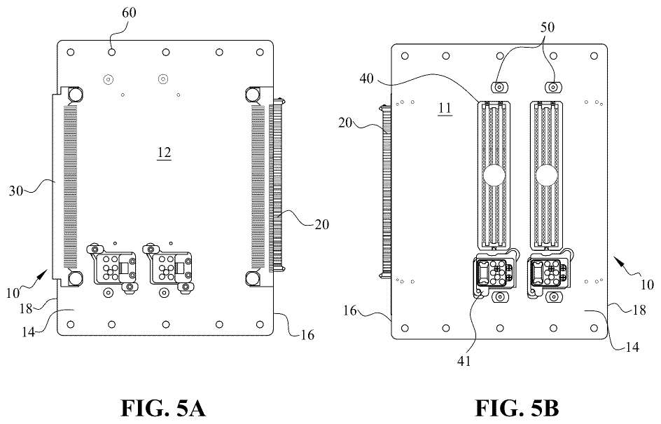

Referring to FIGS. 5A and 5B, in an embodiment, the backplane module 10 may be an RF Aux backplane module, to provide RF signals from a backplane segment of the backplane module 10 to locations outside the chassis or from one module slot to another module slot. RF Aux backplane module 10 includes a plurality of third multi-pin connectors 40 disposed on the first face 11 of the substrate 14. The third multi-pin connectors 40 may include pins in electrical contact with one or more of the plurality of electrical conductors 25. The plurality of third multi-pin connectors 40 for the RF Aux backplane module 10 may be configured and spaced for connection to electronic modules conforming to an open system standard. For example, third multi-pin connectors 40 may be 320-pin Searay™ connectors from Samtec that are left-justified and include a half aperture RF connector 41. Although illustrated with two of the third multi-pin connectors 40, embodiments of RF Aux backplane modules are not limited to this embodiment and may include more than two of the third multi-pin connectors 40.

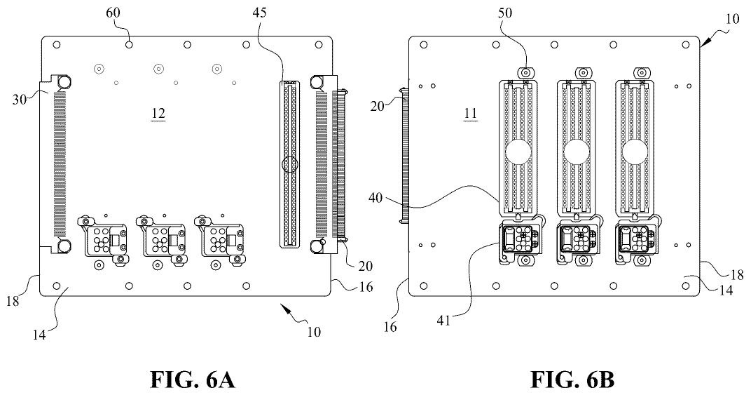

Referring to FIGS. 6A and 6B, in an embodiment, the backplane module 10 may be a digital backplane module. The plurality of third multi-pin connectors 40 for the digital backplane module 10 may be configured and spaced for connection to electronic modules conforming to an open system standard. For example, third multi-pin connectors 40 may be 320-pin Searay™ connectors from Samtec that are left-justified and include a half aperture with RF 41. In the example of FIG. 6B, one third multi-pin connector 40 may be for a wideband (WB)/GPS/Positioning, Navigation, and Timing (PNT) module, another third multi-pin connector 40 may be for a software defined radio (SDR) module, and yet another third multi-pin connector 40 may be for a digital sensor and auxiliary module. Although illustrated with three of the third multi-pin connectors 40, embodiments of digital backplane modules are not limited to this embodiment and may include less than or more than three of the third multi-pin connectors 40.

As illustrated in FIG. 6A, digital backplane module 10 may further include a first mezzanine connector 45 disposed on the second face 12 of the substrate 14 and electrically connected to the plurality of electrical conductors 25. In an example embodiment, the first mezzanine connector 45 may be a first 150-pin Searay™ mezzanine connector from Samtac.

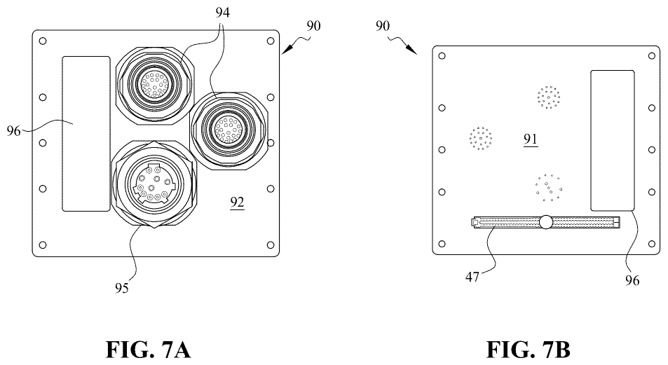

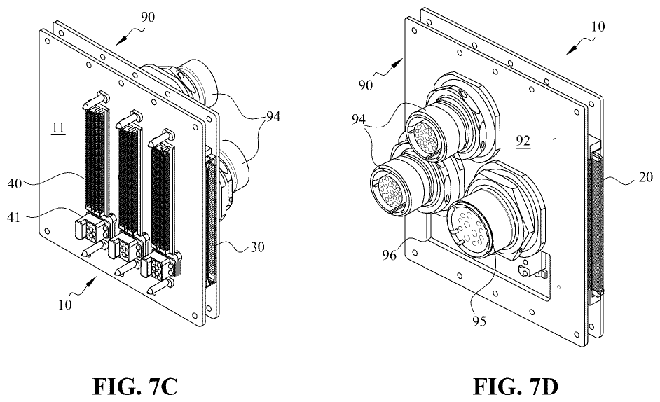

Referring to FIGS. 7A and 7B, in one or more embodiments, a mezzanine card may include a digital input/output transfer circuit board (digital IOTB) 90. Digital IOTB 90 may be formed as a PCB and include a first side 91 and a second side 92. A second mezzanine connector 47, such as a second 150-pin Searay™ mezzanine connector from Samtac, may be disposed on the first side 91 and be configured to physically and electrically interface with the first mezzanine connector 45 in order to connect to a digital backplane module 10. Digital IOTB 90 may also include a cutout portion 96 provided for RF connectors.

A plurality of connectors 94 and 95 may be disposed on and extend from the second side 92 of digital IOTB 90. In an example embodiment, connectors 94 may be 22-pin 2× Ethernet connections and connector 95 may be a 37-pin connection with 3× Serial, Inter-Integrated Circuit (I2C) protocol, 1 Gb Ethernet, 4× discrete IO, USB 2.0, National Marine Electronics Association (NMEA) protocol, one pulse-per-second (1PPS), and 10 MHz reference signal.

As illustrated in FIGS. 7C and 7D, the digital IOTB 90 mezzanine card may be installed onto a backplane module 10 by connecting the first mezzanine connector 45 (not shown) of the backplane module 10 to the second mezzanine connector 47 (not shown) of the digital IOTB 90 mezzanine card.

Such mezzanine cards may support high-speed signals on respective backplane modules 10, thereby supporting the signal integrity of the high-speed signals. Lower-speed signals may be routed between backplane modules due to their lower signal integrity requirements.

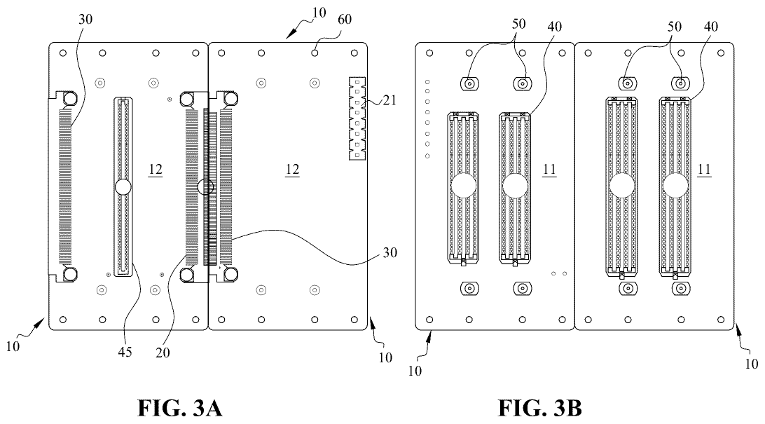

Referring to FIGS. 3A, 3B, 4C, and 4D, one or more embodiments of a modular system backplane may include a plurality of backplane modules 10 connected together wherein at least one backplane module is a power backplane module 10 in accordance with the embodiment of FIGS. 1A and 1B. The power backplane module 10 in accordance with the embodiment of FIGS. 1A and 1B may further be connected to a power circuit board 70 mezzanine card in accordance with FIGS. 1C-1F.

As illustrated in FIGS. 1A, 1B, 3A, 3B, 4C, and 4D, a power backplane module 10 may include a first substrate 14 having a first face 11, a second face 12 opposite the first face 11, a first edge 16 and a second edge 18 opposite and substantially parallel to the first edge 16. A first multi-pin electrical connector 21 may be disposed adjacent the first edge, and may comprise a male 8-pin power connector. A second multi-pin electrical connector 30 may be disposed adjacent the second edge 18. A plurality of first electrical conductors 25 (not visible) may extend between pins of the first multi-pin connector 21 and pins of the second multi-pin connector 30. A plurality of third multi-pin connectors 40 may be disposed on the first face 11 and have pins in electrical contact with one or more of the plurality of first electrical conductors 25. In an example embodiment, the third multi-pin connectors 40 may be 320-pin centered connectors and be configured for at least a filter module and a power supply unit (PSU) module conforming with an open system standard. Although illustrated with two of the third multi-pin connectors 40, embodiments of power backplane modules are not limited to this embodiment and may include more than two of third multi-pin connectors 40.

In the embodiment of FIGS. 3A, 3B, 4C, and 4D, the power backplane module 10 of FIGS. 1A and 1B is connected to a network backplane module of FIGS. 2A and 2B. The network backplane module 10 includes a second substrate 14 having third face 11, a fourth face 12, a third edge 16, and a fourth edge 18 opposite and substantially parallel to the third edge 16. A fourth multi-pin electrical connector 20 may be disposed adjacent the third edge 16 and a fifth multi-pin electrical connector 30 may be disposed adjacent the fourth edge 18. A plurality of second electrical conductors 25 (not visible) may extend between pins of the fourth multi-pin connector 20 and pins of the fifth multi-pin connector 30. The network backplane module 10 may include a plurality of sixth multi-pin connectors 40 disposed on the third face 11 and have pins in electrical contact with one or more of the plurality of second electrical conductors 25.

The plurality of third multi-pin connectors 40 and the plurality of sixth multi-pin connectors 40 may be configured and spaced for connection to electronic modules conforming to the open system standard. In an example embodiment, the sixth multi-pin connectors 40 may be 400-pin centered connectors and be configured for at least an ethernet module and a Single Board Computer (SBC)/Graphics Processing Unit (GPU)/Antenna Interface Unit(AIU) module conforming with the open system standard.

In accordance with one or more embodiments, the power backplane module 10 may be connected to the network backplane module 10, wherein the second multi-pin connector 30 is configured to physically and electrically interface with the fourth multi-pin connector 20.

In an embodiment, at least one of the plurality of third multi-pin connectors 40 of the power backplane module 10 may be configured for a filter module and at least one of the plurality of third multi-pin connectors 40 may be configured for a PSU module. The first multi-pin connector 21 of the power backplane module 10 may be a first eight-pin power mezzanine connector disposed on the second face 12 of the first substrate 14. By disposing the third multi-pin connectors 40 on a first face 11 of substrate 14 and disposing the first multi-pin connector 21 on the second face 12 of substrate 14, electronic modules may be connected to the first face 11 and mezzanine cards may be connected to the second face 12 of power backplane module 10.

Referring to FIGS. 1C-1F, a power circuit board 70 mezzanine card may include a first side 71 and a second side 72. Power circuit board 70 further includes a second eight-pin power mezzanine connector 74 disposed on the first side 71 and configured to physically and electrically interface with the first eight-pin power mezzanine connector 21. A multi-pin power input connector 76 may be disposed on and extend from the second side 72 of power circuit board 70. The power circuit board 70 may also include a power reset switch 78 on second side 72, which may be user-accessible. The power circuit board 70 may be mounted via mezzanine connectors 21 and 74 as a mezzanine card of power backplane card 10, as illustrated in FIGS. 1E and 1F.

Referring to FIG. 3A, the second multi-pin connector 30 may be disposed on the second face 12 of the first substrate 14 of the power backplane module 10, and the fourth multi-pin connector 20 and the fifth multi-pin connector 30 may be disposed on the fourth face 12 of the second substrate 14 of the network backplane module 10. In an embodiment, the second multi-pin connector 30, the fourth multi-pin connector 20, and the fifth multi-pin connector 30 are 150-pin edge connectors, alternating between male and female configurations.

As illustrated in FIG. 3A, the network backplane module 10 may further include a first 150-pin mezzanine connector 45 disposed on the fourth face 12 of the second substrate 14 and electrically connected to the plurality of second electrical conductors 25 (not visible). As shown in FIGS. 4C and 4D, a network IOTB 80 in accordance with FIGS. 4A and 4B may be connected to the network backplane module 10 via a connection of respective mezzanine connectors 47 and 45 (not shown).

Referring to FIGS. 8A, 8B, and 8C, a modular system backplane 100A, 100B, or 100C may be assembled from a plurality of backplane modules 10 attached to each other by edge connectors. The modular system backplane 100A-100C may then be attached to a chassis 15 to provide a plurality of slots having multi-pin connectors for a variety of electronic modules conforming with an open system standard.

In FIG. 8A, a modular system backplane 100A includes a power backplane module connected to an RF Aux backplane module 10. In FIG. 8B, a modular system backplane 100B includes a power backplane module connected to a digital backplane module 10. In FIG. 8C, a modular system backplane 100C includes a power backplane module connected to networking backplane module 10, which in turn is connected to an RF Aux backplane module 10. The modular nature of the backplane modules permits use of a passive backplane operating at a bus frequency and the separation of lower-speed functions operating at the bus frequency, such as power or networking from higher-speed functions operating at speeds higher than the bus frequency, such as digital and/or RF auxiliary functions.

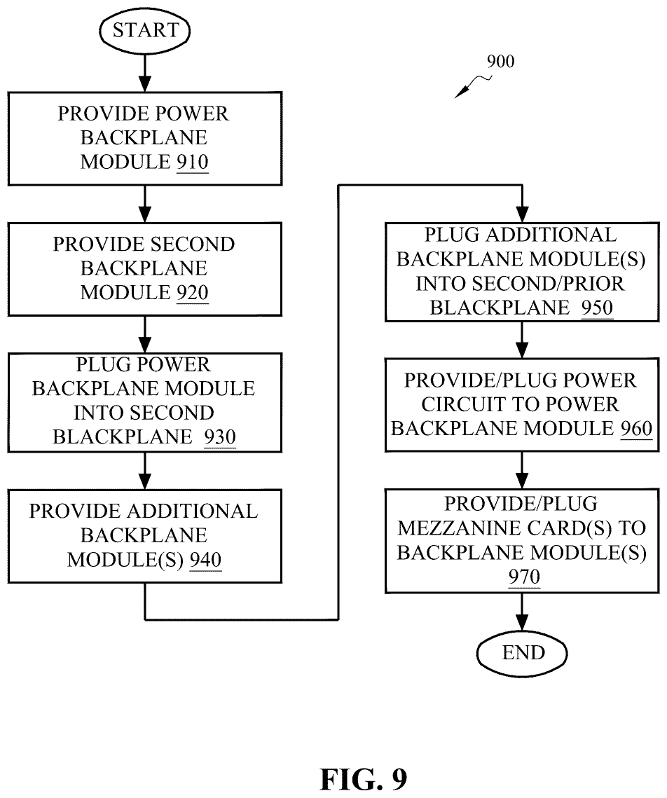

Particular modular system backplanes 100 may be rapidly developed for demonstration or prototyping purposes based upon a series connection of various backplane modules 10. Referring to FIG. 9, an embodiment of a method 900 of providing a modular system backplane 100 is disclosed. Although the steps are disclosed in an order, one of ordinary skill in the art will recognize that various steps can be performed in a different order or simultaneously without departing from the desired result.

Method 900 includes a step 910 of providing a power backplane module 10, a step 920 of providing a second backplane module 10, and a step 930 plugging the power backplane module 10 into the second backplane module 10. The second backplane module 10 may be a network backplane module, an RF Aux backplane module, a digital backplane module, or the like. If only two backplane modules are required to provide the desired functionality, the method 900 may skip to step 960.

If additional functionality is desired, one or more additional backplane modules 10 may be provided at step 940, and at step 950, the additional backplane module(s) 10 may be plugged into the second/prior backplane module 10 using the first and second multi-pin edge connectors 20, 30 in a series manner.

At step 960, a power circuit card 70 may be provided and plugged into the power backplane module 10 in order to provide a power input connector 76 and/or a power reset switch 78. At step 970, any other mezzanine cards, such as network IOTB 80 or digital IOTB 90, may be provided and plugged into corresponding backplane modules 10. Upon completion of these connections, the modular system backplane 100 is complete and method 900 ends. In one or more embodiments, the plurality of multi-pin connectors 40 disposed on the first face 11 of the substrates 14 of the provided backplane modules 10 may be configured and spaced for connection to electronic modules conforming to an open system standard.

In accordance with the concepts of the present disclosure, functionality of a system can be demonstrated with reduced implementation time. Further, by providing an operational system, customers may have an improved understanding of the underlying modular technologies developed in accordance with an open system standard. Rather than demonstrating a system that isn't representative of the function, the inventive concepts provide a system that is representative of the function at the acceptable expense of larger size/weight/power (SWaP) requirements commensurate with a demonstration or prototype system.

While the present disclosure has been particularly described, in conjunction with specific preferred embodiments, it is evident that many alternatives, modifications and variations will be apparent to those skilled in the art in light of the foregoing description. It is therefore contemplated that the appended claims will embrace any such alternatives, modifications and variations as falling within the true scope and spirit of the present disclosure.

What is claimed is:

1. A backplane module for a modular system backplane, comprising:
a substrate having a first face, a second face opposite the first face, a first edge and a second edge opposite and substantially parallel to the first edge;
a first multi-pin electrical connector disposed adjacent the first edge;
a second multi-pin electrical connector disposed adjacent the second edge;
a plurality of electrical conductors extending between pins of the first multi-pin connector and pins of the second multi-pin connector; and
a plurality of third multi-pin connectors disposed on the first face and having pins in electrical contact with one or more of the plurality of electrical conductors,
wherein the first multi-pin connector is a male connector configured to physically and electrically interface with the second multi-pin connector that is a female connector.

2. The backplane module of claim 1, wherein the plurality of third multi-pin connectors is configured and spaced for connection to electronic modules conforming to an open system standard.

3. The backplane module of claim 2, wherein the first multi-pin connector and the second multi-pin connector are disposed on the second face of the substrate, and
wherein the first multi-pin connector and the second multi-pin connector are 150-pin edge connectors.

4. The backplane module of claim 3, further comprising a first 150-pin mezzanine connector disposed on the second face of the substrate and electrically connected to the plurality of electrical conductors.

5. The backplane module of claim 4, further comprising a network input/output transfer circuit board having:
a first side and a second side;
a second 150-pin mezzanine connector disposed on the first side and configured to physically and electrically interface with the first 150-pin mezzanine connector; and
a plurality of networking connectors disposed on and extending from the second side.

6. The backplane module of claim 4, further comprising a digital input/output transfer board having:
a first side and a second side;
a second 150-pin mezzanine connector disposed on the first side and configured to physically and electrically interface with the first 150-pin mezzanine connector;
a cutout configured for RF connections; and
at least one digital input/output connector disposed on and extending from the second side.

7. A modular system backplane, comprising:
a first backplane module including:
a first substrate having a first face, a second face opposite the first face, a first edge and a second edge opposite and substantially parallel to the first edge;
a first multi-pin electrical connector disposed adjacent the first edge;
a second multi-pin electrical connector disposed adjacent the second edge;
a plurality of first electrical conductors extending between pins of the first multi-pin connector and pins of the second multi-pin connector; and
a plurality of third multi-pin connectors disposed on the first face and having pins in electrical contact with one or more of the plurality of first electrical conductors;
a second backplane module including:
a second substrate having third face, a fourth face, a third edge, and a fourth edge opposite and substantially parallel to the third edge;
a fourth multi-pin electrical connector disposed adjacent the third edge;
a fifth multi-pin electrical connector disposed adjacent the fourth edge;
a plurality of second electrical conductors extending between pins of the fourth multi-pin connector and pins of the fifth multi-pin connector; and
a plurality of sixth multi-pin connectors disposed on the third face and having pins in electrical contact with one or more of the plurality of second electrical conductors,
wherein the second multi-pin connector is configured to physically and electrically interface with the fourth multi-pin connector.

8. The modular system backplane of claim 7, wherein the plurality of third multi-pin connectors and the plurality of sixth multi-pin connectors are configured and spaced for connection to electronic modules conforming to an open system standard.

9. The modular system backplane of claim 8, wherein at least one of the plurality of third multi-pin connectors is configured for a filter module and at least one of the plurality of third multi-pin connectors is configured for a power supply unit (PSU) module.

10. The modular system backplane of claim 7, wherein the first multi-pin connector is a first eight-pin power mezzanine connector disposed on the second face of the first substrate.

11. The modular system backplane of claim 10, further comprising a power circuit board having:
a first side and a second side;
a second eight-pin power mezzanine connector disposed on the first side and configured to physically and electrically interface with the first eight-pin power mezzanine connector; and
a multi-pin power input connector disposed on and extending from the second side.

12. The modular system backplane of claim 10, wherein the second multi-pin connector is disposed on the second face of the first substrate, and the fourth multi-pin connector and the fifth multi-pin connector are disposed on the fourth face of the second substrate, and
wherein the second multi-pin connector, the fourth multi-pin connector, and the fifth multi-pin connector are 150-pin edge connectors.

13. The modular system backplane of claim 12, further comprising a first 150-pin mezzanine connector disposed on the fourth face of the second substrate and electrically connected to the plurality of second electrical conductors.

14. The modular system backplane of claim 13, further comprising a network input/output transfer circuit board having:
a first side and a second side;
a second 150-pin mezzanine connector disposed on the first side and configured to physically and electrically interface with the first 150-pin mezzanine connector; and
a plurality of networking connectors disposed on and extending from the second side.

15. The modular system backplane of claim 13, further comprising a digital input/output transfer board having:
a first side and a second side;
a second 150-pin mezzanine connector disposed on the first side and configured to physically and electrically interface with the first 150-pin mezzanine connector;
a cutout configured for RF connections; and
at least one digital input/output connector disposed on and extending from the second side.

16. The modular system backplane of claim 9, wherein the third multi-pin connectors are 320-pin connectors and the sixth multi-pin connectors are 400-pin connectors.

17. The modular system backplane of claim 9, wherein the third multi-pin connectors are 320-pin centered connectors and the sixth multi-pin connectors are 320-pin left-justified/half aperture with RF connectors.

18. A method of providing a modular system backplane, comprising:
providing a first backplane module including:
a first substrate having a first face, a second face opposite the first face, a first edge and a second edge opposite and substantially parallel to the first edge;
a first multi-pin electrical connector disposed adjacent the first edge;
a second multi-pin electrical connector disposed adjacent the second edge;
a plurality of first electrical conductors extending between pins of the first multi-pin connector and pins of the second multi-pin connector; and
a plurality of third multi-pin connectors disposed on the first face and having pins in electrical contact with one or more of the plurality of first electrical conductors;
providing a second backplane module including:
a second substrate having third face, a fourth face, a third edge, and a fourth edge opposite and substantially parallel to the third edge;
a fourth multi-pin electrical connector disposed adjacent the third edge;
a fifth multi-pin electrical connector disposed adjacent the fourth edge;
a plurality of second electrical conductors extending between pins of the fourth multi-pin connector and pins of the fifth multi-pin connector; and
a plurality of sixth multi-pin connectors disposed on the third face and having pins in electrical contact with one or more of the plurality of second electrical conductors;
connecting the second multi-pin connector, physically and electrically, to the fourth multi-pin connector.

19. The method of claim 18, further comprising configuring and spacing the plurality of third multi-pin connectors and the plurality of sixth multi-pin connectors for connection to electronic modules conforming to an open system standard.

20. The method of claim 19, further comprising:
providing an additional backplane module including:
an additional substrate having fifth face, a sixth face, a fifth edge, and a sixth edge opposite and substantially parallel to the fifth edge;
a seventh multi-pin electrical connector disposed adjacent the fifth edge;
a eighth multi-pin electrical connector disposed adjacent the sixth edge;
a plurality of third electrical conductors extending between pins of the sixth multi-pin connector and pins of the fifth multi-pin connector; and
a plurality of ninth multi-pin connectors disposed on the fifth face and having pins in electrical contact with one or more of the plurality of third electrical conductors; and
connecting the fifth multi-pin connector, physically and electrically, to the seventh multi-pin connector.
